(19) United States
(12) Patent Application Publication
(10) Pub. No.: US 2010/0201409 A1
(43) Pub. Date: Aug. 12, 2010

(54) Frequency Divider Circuit

(75) Inventors: Satoshi Terada, Paramus, NJ (US); Masahiro Obuchi, Gunma-ken (JP); Tadahiro Makabe, Gunma-ken (JP)

Correspondence Address: SoCAL IP LAW GROUP LLP, 310 N. WESTLAKE BLVD. STE 120, WESTLAKE VILLAGE, CA, 91362, US

(73) Assignees: Sanyo Electric Co., Ltd., Osaka (JP); Sanyo Semiconductor Co., Ltd., Ora-gun (JP)

(21) Appl. No.: 12/370,326

(22) Filed: Feb. 12, 2009

(51) Int. Cl. H03B 19/00; H03K 21/00

(52) U.S. Cl. 327/117; 327/115

(57) ABSTRACT

A frequency divider circuit includes: a shift register capable of storing at least n-bit data configured to shift an input signal sequentially in synchronization with a clock signal; a pulse generating circuit configured to change the input signal into a pulse form in response to a change in logic level of an output signal from a stage of the shift register among n-bit output signals from the shift register, the stage corresponding to a bit resulting from shifting of the input signal by n bits; and a frequency dividing signal generating circuit configured to generate a frequency dividing signal whose logic level is inverted in response to a change in logic level of an output signal from any one stage of the shift register or logic level of the input signal, in order to divide the clock signal in frequency by a dividing ratio corresponding to the n bits.

### BACKGROUND OF THE INVENTION

1. Field of the Invention

The present invention relates to a frequency divider circuit.

2. Description of the Related Art

Ordinary electronic apparatus may be equipped with a frequency divider circuit to generate a clock signal having a desired frequency (see, e.g., Japanese Patent Application Laid-Open Publication No. 2001-29358). For example, when a highly precise reference clock signal output from a crystal oscillating circuit is divided in frequency by a dividing ratio of 16, a clock signal having a desired frequency can be generated by connecting in series of four frequency divider circuits each with a dividing ratio of 2.

When a clock signal having a desired frequency is generated using a plurality of frequency divider circuits each with a dividing ratio of 2, as described above, signals having frequencies other than the desired frequency are also generated. Specifically, dividing a reference clock signal in frequency by a dividing ratio of 16 results in the generation of clock signals each having each of ½, 1/4, and ⅛ of a frequency of the reference clock signal. Such signals other than the clock signal having the desired frequency become noises in electronic equipment.

### SUMMARY OF THE INVENTION

A frequency divider circuit according to an aspect of the present invention includes: a shift register capable of storing at least n-bit data, the shift register being configured to shift an input signal sequentially in synchronization with a clock signal; a pulse generating circuit configured to change the input signal into a pulse form in response to a change in logic level of an output signal from a stage of the shift register among n-bit output signals from the shift register, the stage corresponding to a bit resulting from shifting of the input signal by n bits; and a frequency dividing signal generating circuit configured to generate a frequency dividing signal whose logic level is inverted in response to a change in logic level of an output signal from any one stage of the shift register, or in response to a change in logic level of the input signal, in order to divide the clock signal in frequency by a dividing ratio corresponding to the number of bits of n.

Other features of the present invention will become apparent from descriptions of this specification and of the accompanying drawings.

### BRIEF DESCRIPTION OF THE DRAWINGS

For more thorough understanding of the present invention and advantages thereof, the following description should be read in conjunction with the accompanying drawings, in which:

FIG. 1 depicts a configuration of a frequency divider circuit 10 of one embodiment of the present invention; and

FIG. 2 is a timing chart for explaining the operation of the frequency divider circuit 10.

### DETAILED DESCRIPTION OF THE INVENTION

At least the following details will become apparent from descriptions of this specification and of the accompanying drawings.

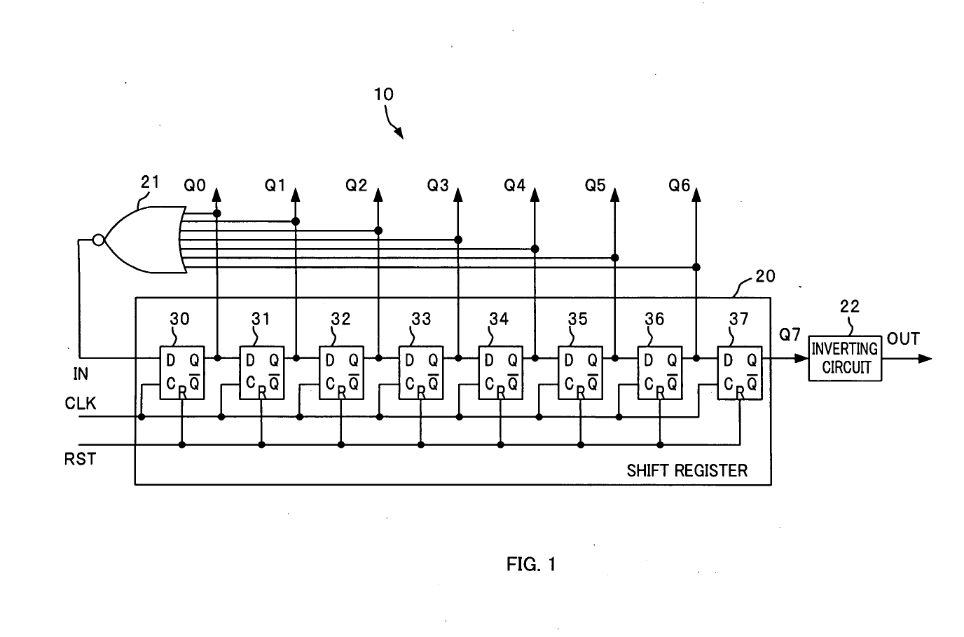

FIG. 1 depicts a configuration of a frequency divider circuit 10 of one embodiment of the present invention. The frequency divider circuit 10 is, for example, the circuit that divides the frequency of a clock signal CLK from a crystal oscillating circuit (not shown) by a dividing ratio of 16. The frequency divider circuit 10 includes a shift register 20, an NOR circuit 21, and an inverting circuit 22. The frequency divider circuit 10 is controlled by, for example, a microcomputer (not shown).

The shift register 20 includes D flip-flop circuits 30 to 37. The D flip-flop 30 is reset when a reset signal RST from the microcomputer (not shown) becomes high level, which changes a Q output of the D flip-flop 30 to low level. When the reset signal RST becomes low level, the D flip-flop 30 is released from a reset state. The D flip-flop circuit 30 then outputs from the Q output thereof an input signal IN received at a D input thereof in synchronization with a clock signal CLK. Each of D flip-flops 31 to 37 of this embodiment is identical with the D flip-flop 30. Consequently, the D flip-flops 30 to 37 shift the incoming input signal IN sequentially in synchronization with the clock signal CLK. The shift register 20 of this embodiment is, therefore, equivalent to an 8-bit shift resistor. In this embodiment, output signals output from Q outputs of the D flip-flops 30 to 37 will be referred to as output signals Q0 to Q7, respectively.

The NOR circuit 21 (pulse generating circuit) is the circuit that calculates the negative logical sum of output signals Q1 to Q6. In this embodiment, a result of calculation of a negative logical sum at the NOR circuit 21 is equivalent to the input signal IN that is input to the D input of the D flip-flop 30. Because of this, for example, when the shift register 20 is reset in response to the reset signal RST to change output signals Q0 to Q6 to low level, the input signal IN becomes high level. On the other hand, when any one of the output signals Q0 to Q6 becomes high level, the input signal IN becomes low level.

The inverting circuit 22 (frequency dividing signal generating circuit) is the circuit that inverts the logic level of an output signal OUT (frequency dividing signal) in synchronization with a rising edge of an output signal Q7.

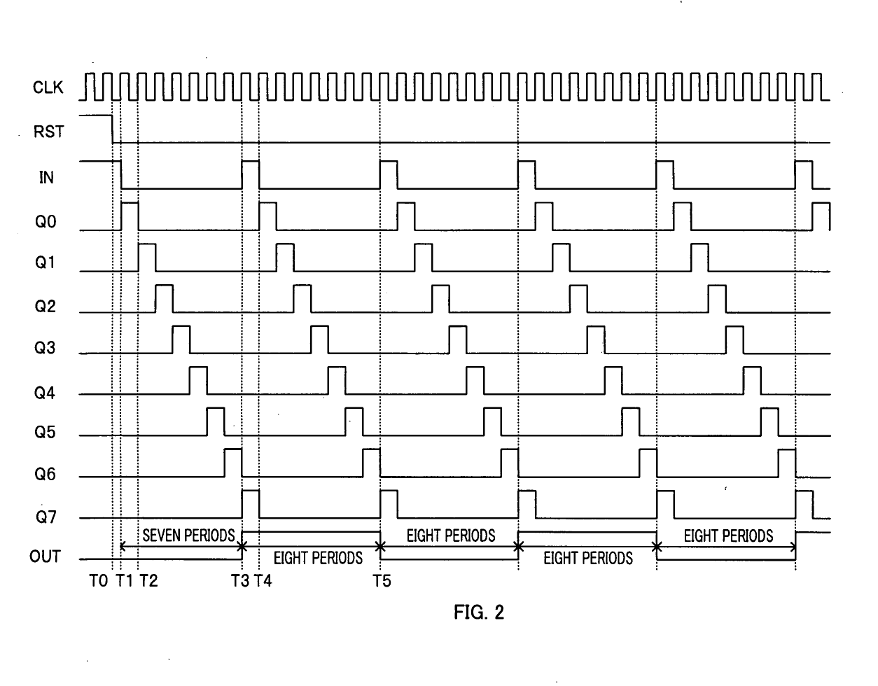

The operation of the frequency divider circuit 10 will be described referring to a timing chart of FIG. 2, where it is assumed that the shift register 20 is reset, and that an output signal from the inverting circuit 22 is low level. The input signal IN output from the NOR circuit 21 is, therefore, high level.

When the microcomputer (not shown) sets the reset signal RST low level at a time T0, the shift register 20 is released from a reset state. At a time T1 when the clock signal is changed to high level after the release of the shift register 20 from the reset state, the D flip-flop 30 changes an output signal Q0 from the Q output of the D flip-flop 30 to high level, based on the high-level input signal IN. That is, the high-level input signal IN is stored in the D flip-flop 30 as the first stage of the 8-bit shift register 20. When the output signal Q0 becomes high level, the NOR circuit 21 changes the input signal IN to low level.

At a time T2 when one period of the clock signal CLK has elapsed after the time T1, the D flip-flop 31 changes an output signal Q1 from the Q output of the D flip-flop 31 to high level, based on the high-level output signal Q0. Meanwhile, the D flip-flop 30 changes the output signal Q0 to low level because the input signal IN is low level at this moment. In this manner, the shift register 20 shifts the input signal IN sequentially in synchronization with the clock signal CLK.

At a time T3 when seven periods of the clock signal CLK have elapsed after the time T1, that is, when the high-level input signal IN stored in the first stage of the shift register 20 is shifted by seven bits and thereafter stored in the D flip-flop 37 as the eighth stage of the shift register 20, output signals Q1 to Q6 become low level. As a result, the NOR circuit 21 changes the input signal IN to high level. At this time, because an output signal Q7 becomes high level, the inverting circuit 22 inverts the output signal OUT from low level to high level.

At a time T4 when one period of the clock signal CLK has elapsed after the time T3, the shift register 20 shifts the high-level input signal IN by one bit. Because the output signal Q0 becomes high level at this time, the NOR circuit 21 changes the input signal IN to low level. That is, the NOR circuit 21 changes the input signal IN into a pulse form during one period of the clock signal CLK between the times T3 and T4. The input signal IN changed into the pulse form is shifted sequentially in synchronization with the clock signal CLK.

In this embodiment, any one of the output signals Q0 to Q6 is high level in a time period over which the input signal IN changed into the pulse form is shifted to D flip-flop 37 as the eighth stage of the shift resister 20. As a result, the NOR circuit 21 keeps outputting the low-level input signal IN during the time period. When the input signal IN changed into the pulse form has been shifted by eight bits, that is, at a time T5 when the output signal Q6 from the seventh stage of the shift register 20 is changed from high level to low level, the NOR circuit 21 changes the input signal IN to high level to change the input signal IN again into the pulse form. As a result, at the time T5, the inverting circuit 22 inverts the logic level of the output signal OUT in the same manner as at the time T3, and thereby the inverting circuit 22 changes the output signal OUT to low level. The NOR circuit 21 changes the input signal IN to high level to generate the input signal IN of the pulse form that is to be input to the shift register 20. Afterward, in the frequency divider circuit 10, the operation carried out between the time T3 and the time T5 is repeated in synchronization with the clock signal CLK. The output signal OUT is, therefore, inverted in logic level at every eight periods of the clock signal CLK. Hence the output signal OUT is output as a signal obtained by dividing the clock signal CLK in frequency by a dividing ratio of 16.

In the frequency dividing circuit 10 having the above configuration of this embodiment, the NOR circuit 21 changes the input signal IN into the pulse form when the output signal Q6 from the seventh stage of the 8-bit shift register 20 changes from high level to low level. The input signal IN of the pulse form remaining high during one period of the clock signal CLK is then shifted again in synchronization with the clock signal CLK. Then, when the output signal Q6 from the seventh stage of the shift resister 20 changes from high level to low level, the NOR circuit 21 changes the input signal IN into the pulse form again in a repetitive manner. As a result, the logic level of any output signal from one stage among the output signals Q0 to Q7 from the shift register 20 of this embodiment changes from high level to low level at every eight periods of the clock signal CLK. In the frequency divider circuit 10 of this embodiment, the logic level of the output signal OUT is inverted in synchronization with each rising edge of the output signal Q7 that is changed to high level at every eight periods of the clock signal CLK. The frequency divider circuit 10 is, therefore, capable of outputting the desired output signal OUT divided in frequency by a dividing ratio of 16 without generating unnecessary signals having ½, 1/4, etc., of the frequency of the clock signal CLK.

According to this embodiment, when all of the output signals Q0 to Q6 corresponding respectively to the outputs from the first to seventh stages of the shift register 20 become low level, the input signal IN is changed to high level. When the high-level input signal IN is shifted and the output signal Q0 becomes high level, the input signal IN is then changed to low level. This results in the generation of the input signal IN of a pulse form that becomes high level at every eight periods of the clock signal CLK. In this embodiment, the frequency divider circuit 10 divides the clock signal CLK in frequency by a dividing ratio of 16, based only on the input signal IN of the pulse form that becomes high level at every eight periods of the clock signal CLK. The frequency divider circuit 10, therefore, does not generate unnecessary signals having ½, 1/4, etc., of the frequency of the clock signal CLK, which unnecessary signals are generated, for example, when a plurality of frequency divider circuits each with a dividing ratio of 2 are used for frequency division.

According to this embodiment, the NOR circuit 21 generates the input signal IN of the pulse form that becomes high level at every eight periods of the clock signal CLK. This enables generation of the input signal IN of the pulse form that becomes high level at every eight periods of the clock signal CLK without using a complicated logical circuit.

The above embodiments of the present invention are simply for facilitating the understanding of the present invention and are not in any way to be construed as limiting the present invention. The present invention may variously be changed or altered without departing from its spirit and encompass equivalents thereof.

For example, the inverting circuit 22 of this embodiment inverts the logic level of the output signal OUT, based on a rising edge of the output signal Q7. This, however, is not the only method of inverting the logic level of the output signal OUT. Specifically, the same effect as achieved in this embodiment can be achieved by selecting any one signal from its corresponding stage out of the output signals Q0 to Q7 and the input signal IN, and reversing the logic level of the output signal OUT in synchronization with a rising edge of the selected signal.

In this embodiment, the clock signal CLK is divided in frequency by a dividing ratio of 16 using the 8-bit shift register 20. The number of bits of the shift register, however, is not limited to 8. For example, by use of an m-bit shift register, the negative logical sum of output signals from m stages can be calculated to generate an input signal, and by connecting the inverting circuit 22 to any one stage among m stages, a signal divided in frequency by a dividing ratio of (m+1)×2 can be generated. In this case, the signal divided in frequency by the dividing ratio of (m+1)×2 can be generated without generating unnecessary signals having undesired frequencies in the same manner as in this embodiment.

The frequency divider circuit 10 of this embodiment is provided with the NOR circuit 21 for changing the input signal IN into a pulse form. The NOR circuit 21, however, is not the only option. For example, the frequency divider circuit 10 may be provided with an inverter that inverts the logic level of the output signal Q6 among the output signals Q0 to Q6 so that an output signal from the inverter is taken to be the input signal IN. In this case, the input signal IN can be changed into the pulse form in response to a change in logic level of the output signal Q6 to offer the same effect as achieved in this embodiment.

What is claimed is:

1. A frequency divider circuit comprising:
a shift register capable of storing at least n-bit data, the shift register being configured to shift an input signal sequentially in synchronization with a clock signal;
a pulse generating circuit configured to change the input signal into a pulse form in response to a change in logic level of an output signal from a stage of the shift register among n-bit output signals from the shift register, the stage corresponding to a bit resulting from shifting of the input signal by n bits; and
a frequency dividing signal generating circuit configured to generate a frequency dividing signal whose logic level is inverted in response to a change in logic level of an output signal from any one stage of the shift register, or in response to a change in logic level of the input signal, in order to divide the clock signal in frequency by a dividing ratio corresponding to the number of bits of n.

2. The frequency dividing circuit of claim 1, wherein
the pulse generating circuit is configured to
change a logic level of the input signal to one logic level, when logic levels of all of the n-bit output signals from the shift register becomes the other logic level, and
change a logic level of the input signal to the other logic level, when a logic level of an output signal from any one stage of the shift register among the n-bit output signals from the shift register becomes the one logic level.

3. The frequency dividing circuit of claim 2, wherein
the pulse generating circuit includes
a negative logical sum circuit configured to change the input signal according to a result of calculation of a negative logical sum based on all of the n-bit output signals from the shift register.
